(19) United States
(12) Patent Application Publication
(10) Pub. No.: US 2025/0203848 A1
(43) Pub. Date: Jun. 19, 2025

(54) SEMICONDUCTOR DEVICE AND MANUFACTURING METHOD THEREOF

(71) Applicant: Fujian Jinhua Integrated Circuit Co., Ltd., Quanzhou City (CN)

(72) Inventor: Huixian LAI, Quanzhou City (CN)

(73) Assignee: Fujian Jinhua Integrated Circuit Co., Ltd., Quanzhou City (CN)

(21) Appl. No.: 18/404,869

(22) Filed: Jan. 4, 2024

(30) Foreign Application Priority Data
Dec. 15, 2023 (CN) 202311745688.1

(51) Int. Cl. H10B 12/00

(52) U.S. Cl. CPC H10B 12/482; H10B 12/09; H10B 12/50

(57) ABSTRACT

A semiconductor device includes a semiconductor substrate including a fin-shaped structure, a first stacked structure disposed in the semiconductor substrate, and a contact structure. The first stacked structure extends in a horizontal direction and is disposed straddling the fin-shaped structure. The first stacked structure includes an electrically conductive layer including a first portion and a second portion, a capping layer disposed on the electrically conductive layer, and a dielectric capping layer disposed on the capping layer and the electrically conductive layer. A top surface of the second portion is higher than the top surface of the first portion. A distance between the top surface of the second portion and the isolation structure is greater than a distance between the top surface of the first portion and the isolation structure. The contact structure directly contacts the second portion and is electrically connected with the first stacked structure.

### BACKGROUND OF THE INVENTION

### 1. Field of the Invention

The present invention relates to a semiconductor technical field, and more particularly, to a semiconductor device and a manufacturing method thereof.

### 2. Description of the Prior Art

Dynamic random access memory (DRAM) is a kind of volatile storage device which is an indispensable key part of many electronic products. DRAM includes a great number of memory cells arranged for forming an array configured to store data. Each of the memory cells may be composed of a metal oxide semiconductor (MOS) transistor and a capacitor connected in series.

The MOS transistor structure of the memory cell has many different structural designs because of considerations such as product requirements and/or memory cell density. Therefore, the MOS transistor structure of the memory cell may be different from the transistor structure in other regions on the same chip, and the manufacturing process becomes complicated accordingly. Therefore, how to effectively integrate the manufacturing processes of memory cells and components in other regions is a very important issue for related industries.

### SUMMARY OF THE INVENTION

A semiconductor device and a manufacturing method thereof are provided in the present invention for improving an electrically connection between a contact structure and a stacked structure, and manufacturing yield of the semiconductor device may be enhanced accordingly.

According to an embodiment of the present invention, a semiconductor device is provided. The semiconductor device includes a semiconductor substrate, a first stacked structure, and a contact structure. The semiconductor substrate includes an isolation structure and an active structure defined by the isolation structure. The active structure includes at least one fin-shaped structure. The first stacked structure is disposed in the semiconductor substrate. The first stacked structure extends in a horizontal direction and is disposed straddling the fin-shaped structure, and the first stacked structure includes an electrically conductive layer, a capping layer, and a dielectric capping layer. The electrically conductive layer includes a first portion and a second portion. A top surface of the second portion is higher than a top surface of the first portion in a vertical direction, and a distance between the top surface of the second portion and the isolation structure in the vertical direction is greater than a distance between the top surface of the first portion and the isolation structure in the vertical direction. The capping layer is disposed on the electrically conductive layer. The dielectric capping layer is disposed on the capping layer and the electrically conductive layer. The contact structure directly contacts the second portion of the electrically conductive layer and is electrically connected with the first stacked structure.

According to an embodiment of the present invention, a manufacturing method of a semiconductor device is provided. The manufacturing method includes the following steps. A semiconductor substrate is provided. The semiconductor substrate includes an isolation structure and an active structure defined by the isolation structure. The active structure includes at least one fin-shaped structure. A stacked structure is formed in the semiconductor substrate. The stacked structure extends in a horizontal direction and is disposed straddling the fin-shaped structure, and the stacked structure includes an electrically conductive layer, a capping layer, and a dielectric capping layer. The electrically conductive layer includes a first portion and a second portion. A top surface of the second portion is higher than a top surface of the first portion in a vertical direction, and a distance between the top surface of the second portion and the isolation structure in the vertical direction is greater than a distance between the top surface of the first portion and the isolation structure in the vertical direction. The capping layer is disposed on the electrically conductive layer. The dielectric capping layer is disposed on the capping layer and the electrically conductive layer. A contact structure is formed. The contact structure directly contacts the second portion of the electrically conductive layer and is electrically connected with the stacked structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a top view schematic drawing illustrating a semiconductor device according to an embodiment of the present invention.

FIG. 2 is a cross-sectional schematic drawing illustrating a semiconductor device according to a first embodiment of the present invention.

FIG. 3 is another cross-sectional schematic drawing illustrating the semiconductor device according to the first embodiment of the present invention.

FIGS. 4-13 are schematic drawings illustrating a manufacturing method of a semiconductor device according to an embodiment of the present invention, wherein FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, FIG. 12 is another cross-sectional schematic drawing illustrating the condition of FIG. 11, and FIG. 13 is a cross-sectional schematic drawing illustrating another region under the condition of FIG. 11.

FIG. 14 is a cross-sectional schematic drawing illustrating a semiconductor device according to a second embodiment of the present invention.

FIG. 15 is a cross-sectional schematic drawing illustrating a semiconductor device according to a third embodiment of the present invention.

FIG. 16 is a cross-sectional schematic drawing illustrating a semiconductor device according to a fourth embodiment of the present invention.

FIG. 17 is a cross-sectional schematic drawing illustrating a semiconductor device according to a fifth embodiment of the present invention.

FIG. 18 is a cross-sectional schematic drawing illustrating a semiconductor device according to a sixth embodiment of the present invention.

### DETAILED DESCRIPTION

To provide a better understanding of the presented invention for those skilled in the technical field of the present invention, several preferred embodiments of the present invention are enumerated below, together with the accompanying drawings, to describe the technical solutions and desired effects of the present invention in detail. Those skilled in the art may refer to the following embodiments and replace, reorganize, and mix features in several different embodiments to complete other embodiments without departing from the spirit of the present invention

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

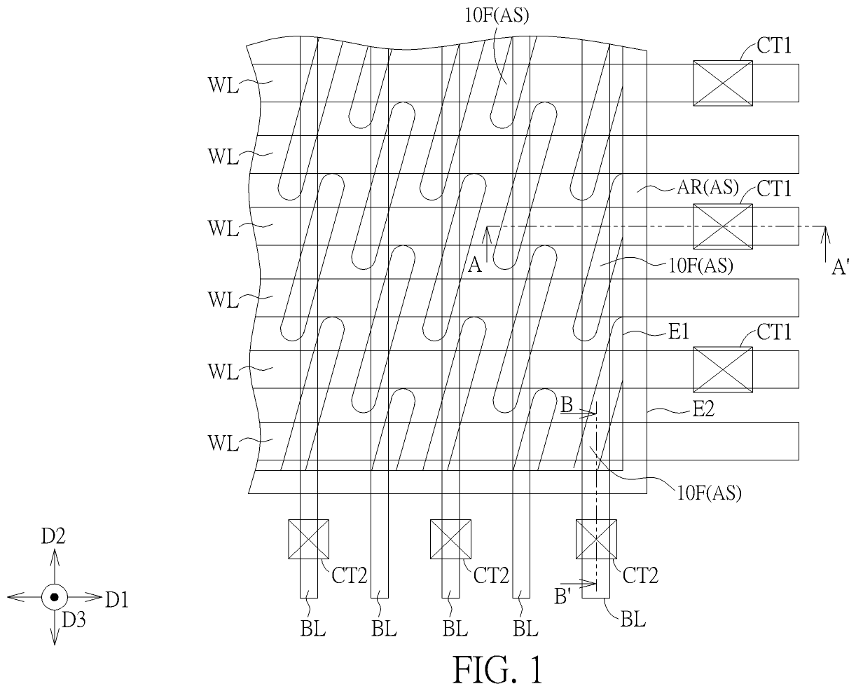

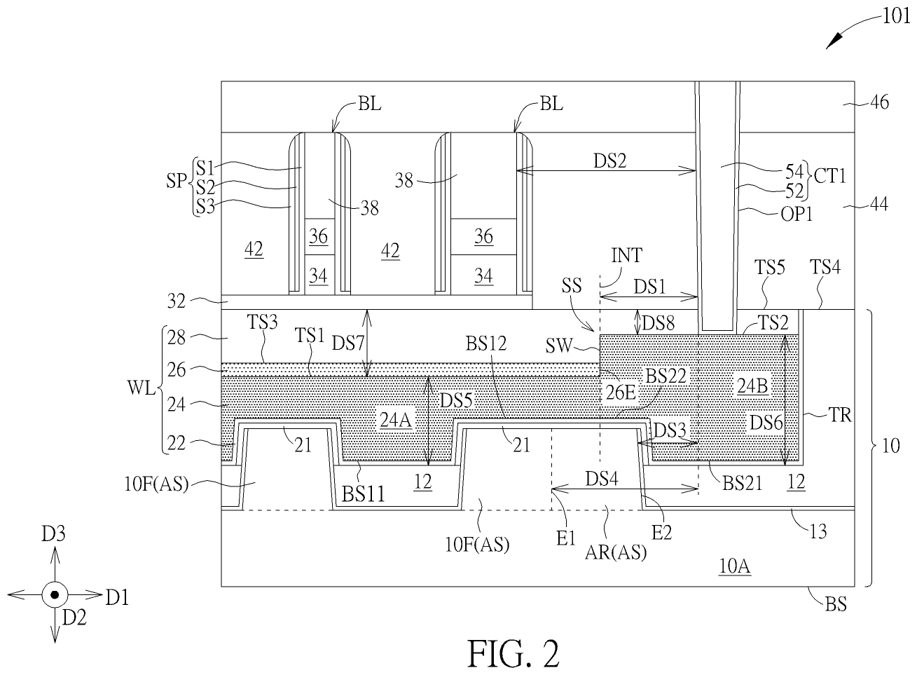

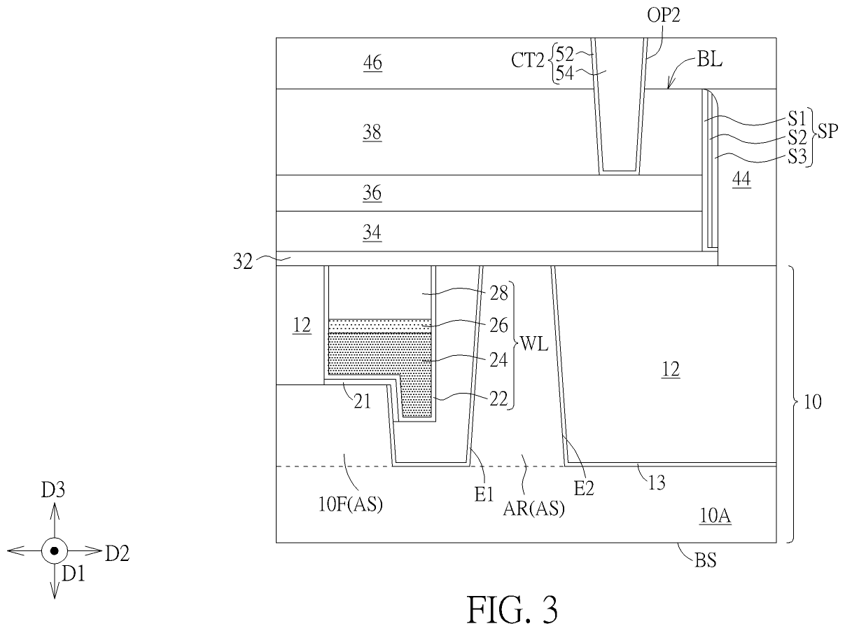

Please refer to FIG. 1, FIG. 2, and FIG. 3. FIG. 1 is a top view schematic drawing illustrating a semiconductor device according to an embodiment of the present invention, FIG. 2 is a cross-sectional schematic drawing illustrating a semiconductor device according to a first embodiment of the present invention, and FIG. 3 is another cross-sectional schematic drawing illustrating the semiconductor device in the first embodiment of the present invention. In some embodiments, at least a portion of FIG. 2 may be regarded as a cross-sectional diagram taken along a line A-A′ in FIG. 1, and at least a portion of FIG. 3 may be regarded as a cross-sectional diagram taken along a line B-B′ in FIG. 1, but not limited thereto. As shown in FIG. 1, FIG. 2, an FIG. 3, the semiconductor device includes a semiconductor substrate 10, a first stacked structure WL, and a contact structure CT1. The semiconductor substrate 10 includes an isolation structure 12 and an active structure AS defined by the isolation structure 12. The active structure AS includes at least one fin-shaped structure 10F. The first stacked structure WL is disposed in the semiconductor substrate 10. The first stacked structure WL extends in a horizontal direction D1 and is disposed straddling the fin-shaped structure 10F, and the first stacked structure WL includes an electrically conductive layer 24, a capping layer 26, and a dielectric capping layer 28. The capping layer 26 is disposed on the electrically conductive layer 24, and the dielectric capping layer 28 is disposed on the capping layer 26 and the electrically conductive layer 24. The electrically conductive layer 24 includes a first portion 24A and a second portion 24B. A top surface TS2 of the second portion 24B is higher than a top surface TS1 of the first portion 24A in a vertical direction D3, and a distance DS6 between the top surface TS2 of the second portion 24B and the isolation structure 12 in the vertical direction D3 is greater than a distance DS5 between the top surface TS1 of the first portion 24A and the isolation structure 12 in the vertical direction D3. The contact structure CT1 directly contacts the second portion 24B of the electrically conductive layer 24 and is electrically connected with the first stacked structure WL. By the above-mentioned thickness distribution design of the electrically conductive layer 24 in the first stacked structure WL, the etching amount required for forming an opening OP1 corresponding to the contact structure CT1 may be reduced, and it is beneficial for integrating the manufacturing process of the contact structure CT1 and manufacturing processes of other contact structures. The purposes of simplifying the overall manufacturing process and/or improving the manufacturing yield of the semiconductor device may be achieved accordingly.

In some embodiments, the semiconductor substrate 10 may include a silicon substrate, a silicon germanium semiconductor substrate, a silicon-on-insulator (SOI) substrate, or a substrate made of other suitable materials. In addition, at least a part of the semiconductor substrate except the isolation structure 12 may be regarded as a base layer 10A. The base layer 10A may include the semiconductor material described above in the semiconductor substrate 10, the active structure AS may be regarded as a part of the base layer 10A, and the isolation structure 12 may be regarded as being disposed in the base layer 10A for defining the active structure AS in the base layer 10A. In addition, the active structure AS may be formed by performing a patterning process to the base layer 10A, and the active structure AS may include the semiconductor material of the semiconductor substrate 10 (such as silicon, but not limited thereto) accordingly. The isolation structure 12 may include a single layer or multiple layers of insulation materials, such as an oxide insulation material, a nitride insulation material, or other suitable insulation materials. In some embodiments, the isolation structure 12 may surround the active structure AS in horizontal directions, and the active structure AS may further include a peripheral structure AR surrounding the fin-shaped structure 10F described above (such as in a top view schematic drawing of the semiconductor device). The first stacked structure WL may extend in the horizontal direction D1 and be disposed straddling the peripheral structure AR. In some embodiments, the active structure AS may include a plurality of the fin-shaped structures 10F isolated from one another by the isolation structure 12, and the peripheral structure AR may surround the fin-shaped structures 10F in the horizontal directions (such as the horizontal direction D1, a horizontal direction D2, and other horizontal directions orthogonal to the vertical direction D3) and may be connected with some of the fin-shaped structures 10F. In addition, the peripheral structure AR may have an inner edge (such as an edge E1) facing the fin-shaped structures 10F and an outer edge (such as an edge E2) opposite to the inner edge. The area surrounded by the inner edge may be regarded as a cell region of the semiconductor device, and a region that the outer edge faces may be regarded as a peripheral region of the semiconductor device, but not limited thereto.

In some embodiments, the vertical direction D3 may be regarded as a thickness direction of the semiconductor substrate 10, and the semiconductor substrate 10 may have a top surface and a bottom surface BS opposite to the top surface in a vertical direction D3. In this description, a distance between the bottom surface BS of the semiconductor substrate 10 and a relatively higher location and/or a relatively higher part in the vertical direction D3 may be greater than a distance between the bottom surface BS of the semiconductor substrate 10 and a relatively lower location and/or a relatively lower part in the vertical direction D3. The bottom or a lower portion of each component may be closer to the bottom surface BS of the semiconductor substrate 10 in the vertical direction D3 than the top or upper portion of this component. Another component disposed above a specific component may be regarded as being relatively far from the bottom surface BS of the semiconductor substrate 10 in the vertical direction D3, and another component disposed under a specific component may be regarded as being relatively close to the bottom surface BS of the semiconductor substrate 10 in the vertical direction D3. Additionally, in this description a top surface of a specific component may include the topmost surface of this component in the vertical direction D3, and a bottom surface of a specific component may include the bottommost surface of this component in the vertical direction D3, but not limited thereto.

In some embodiments, the semiconductor device 101 may further include a stress material layer 13 and an oxide layer 21, the stress material layer 13 may be disposed between the isolation structure 12 and the base layer 10A, and the oxide layer 21 may be partly disposed between the first stacked structure WL and the active structure AS and partly disposed between the first stacked structure WL and the stress material layer 13. The stress material layer 13 may include a germanium-containing layer capable of providing required stress and having a better lattice structure, such as a material layer including germanium and/or silicon germanium, but not limited thereto. For example, the stress material layer 13 may include silicon germanium or germanium, the base layer 10A and the active structure AS may include silicon, and the lattice structure of the base layer 10A and the active structure AS may be improved accordingly. In some embodiments, the stress material layer 13 may include other materials capable of providing required stress and improving the lattice structure, such as carbide, silicon carbide, and so forth. The oxide layer 21 disposed between the first stacked structure WL and the active structure AS may include an element identical to that in the material of the active structure AS, and the oxide layer 21 disposed between the first stacked structure WL and the active structure AS may include silicon oxide for example, but not limited thereto. The oxide layer 21 disposed between the first stacked structure WL and the stress material layer 13 may include an element identical to that in the material of the stress material layer 13, and the oxide layer 21 disposed between the first stacked structure WL and the stress material layer 13 may include silicon germanium oxide or germanium oxide for example, but not limited thereto.

In some embodiments, the semiconductor device 101 may include a plurality of the first stacked structures WL, each of the first stacked structures WL may extend in the horizontal direction D1, the first stacked structures WL may be arranged repeatedly in the horizontal direction D2, and the horizontal direction D2 may be substantially orthogonal to the horizontal direction D1, but not limited thereto. Each of the first stacked structures WL may be disposed in a trench TR located in the semiconductor substrate 10, and each of the first stacked structures WL may extend in the horizontal direction D1 for being disposed straddling the fin-shaped structures 10F and the peripheral structure AR. In some embodiments, the first stacked structure WL may further include a dielectric layer 22 located in the trench TR, and the dielectric layer 22 may be partly disposed between the electrically conductive layer 24 and the active structure AS and partly disposed between the electrically conductive layer 24 and the isolation structure 12, such as being partly disposed between the electrically conductive layer 24 and the isolation structure 12 in the horizontal direction D1, but not limited thereto. The dielectric layer 22 may include a high dielectric constant (high-k) dielectric material or other suitable dielectric materials. The high-k dielectric material described above may include hafnium oxide (HfO_{X}), hafnium silicon oxide (HfSiO₄), hafnium silicon oxynitride (HfSiON), aluminum oxide (Al₂O₃), tantalum oxide (Ta₂O₅), zirconium oxide (ZrO₂), or other suitable high-k dielectric materials. The electrically conductive layer 24 may include a single layer or multiple layers of electrically conductive materials, such as titanium nitride, titanium carbide, tantalum nitride, tantalum carbide, tungsten nitride, tungsten carbide, titanium aluminide, aluminum nitride, titanium, tungsten, aluminum, copper, tantalum, or other suitable metallic or nonmetallic electrically conductive materials. The capping layer 26 may include doped polycrystalline silicon, undoped polycrystalline silicon, or other materials different from the electrically conductive layer 24 and the dielectric capping layer 28. In some embodiments, the electrically conductive layer 24 has a first work function, the capping layer 26 has a second work function, and the first work function is greater than the second work function, but not limited thereto. The dielectric capping layer 28 may include silicon nitride, silicon oxide, silicon oxynitride, a combination of the materials described above, or other suitable dielectric materials.

The thickness of the second portion 24B of the electrically conductive layer 24 may be substantially greater than the thickness of the first portion 24A, and the second portion 24B is directly connected with the first portion 24A. The electrically conductive layer 24 may be partly disposed above the isolation structure 12 and partly disposed above the active structure AS in the vertical direction D3. A bottom surface of the first portion 24A of the electrically conductive layer 24 (such as a bottom surface BS11) and a bottom surface of the second portion 24B (such as a bottom surface BS21) may be disposed above the isolation structure 12 in the vertical direction D3, and another bottom surface of the first portion 24A (such as a bottom surface BS12) and/or another bottom surface of the second portion 24B (such as a bottom surface BS22) may be disposed above the active structure AS in the vertical direction D3. A thickness of the second portion 24B disposed above the isolation structure 12 in the vertical direction D3 is greater than a thickness of the first portion 24A disposed above the isolation structure 12 in the vertical direction D3, and a thickness of the second portion 24B disposed above the active structure AS in the vertical direction D3 is greater than a thickness of the first portion 24A disposed above the active structure AS in the vertical direction D3. In some embodiments, a sidewall SW of the second portion 24B of the electrically conductive layer 24 may be located at an interface between the second portion 24B and the first portion 24A (such as an interface INT), and the sidewall SW may face the capping layer 26 in the horizontal direction D3. In addition, the surface of the electrically conductive layer 24 may include a ladder-shaped structure SS. For example, the sidewall SW may be connected with the top surface TS1 of the first portion 24A and the top surface TS2 of the second portion 24B to form the ladder-shaped structure SS, and the top surface TS1 of the first portion 24A and the top surface TS2 of the second portion 24B may be located at two opposite sides of the ladder-shaped structure SS in the horizontal direction D1, respectively, but not limited thereto. In some embodiments, the top surface TS2 of the second portion 24B of the electrically conductive layer 24 may be higher than a top surface TS3 of the capping layer 26 in the vertical direction D3, and the top surface TS2 of the second portion 24B is not covered by the capping layer 26. Therefore, the dielectric capping layer 28 may directly contact the sidewall SW and the top surface TS2 of the second portion 24B of the electrically conductive layer 24 and the top surface TS3 of the capping layer 26, and the capping layer 26 (such as an edge 26E of the capping layer 26 facing the contact structure CT1 in the horizontal direction D1) may directly contact the sidewall SW of the second portion 24B and the top surface TS1 of the first portion 24A. Additionally, because a top surface of the dielectric capping layer 28 located on the second portion 24B of the electrically conductive layer 24 and a top surface of the dielectric capping layer 28 located on the first portion 24A of the electrically conductive layer 24 are located at the same level substantially, a distance DS8 between a top surface TS5 of the dielectric capping layer 28 and the top surface TS2 of the second portion 24B of the electrically conductive layer 24 in the vertical direction D3 may be less than a distance DS7 between the top surface TS5 of the dielectric capping layer 28 and the top surface TS1 of the first portion 24A of the electrically conductive layer 24 in the vertical direction D3.

In some embodiments, the contact structure CT1 may directly contact the top surface TS2 of the second portion 24B of the electrically conductive layer 24, and the sidewall SW of the second portion 24B of the electrically conductive layer 24 and the edge 26E of the capping layer 26 may be separated from the contact structure CT1. A distance DS1 may be defined as a distance between the contact structure CT1 and the edge 26E of the capping layer 26 in the horizontal direction D1 and/or a distance between the contact structure CT1 and the sidewall SW of the second portion 24B of the electrically conductive layer 24 in the horizontal direction D1, a distance DS3 may be defined as a distance between the contact structure CT1 and the peripheral structure AR adjacent to the contact structure CT1 in the horizontal direction D1, and a distance DS4 may be defined as a distance between the edge E1 of the peripheral structure AR and the contact structure CT1 in the horizontal direction D3, but not limited thereto. In some embodiments, the edge 26E of the capping layer 26 and the sidewall SW of the second portion 24B of the electrically conductive layer 24 may be located above the active structure AS (such as the peripheral structure AR, but not limited thereto), and the distance DS1 described above may be greater than the distance DS3 and less than the distance DS4 accordingly, but not limited thereto. Additionally, in some embodiments, the contact structure CT1 may extend downwards in the vertical direction D3 for being partly located in the second portion 24B of the electrically conductive layer 24, and a bottom surface of the contact structure CT1 may be slightly lower than the top surface TS2 of the second portion 24B of the electrically conductive layer 24 in the vertical direction D3 and higher than the top surface TS1 of the first portion 24A of the electrically conductive layer 24 in the vertical direction D3 accordingly.

In some embodiments, the semiconductor device 101 may further include a plurality of second stacked structures BL and a plurality of insulation patterns 42 disposed above the semiconductor substrate 10. Each of the second stacked structures BL may extend in the horizontal direction D2 to be disposed above the peripheral structure AR, the cell region, and the peripheral region described above, and each of the fin-shaped structures 10F may extend in another horizontal direction different from the horizontal direction D1 and the horizontal direction D2. In addition, the second stacked structures BL may be arranged repeatedly in the horizontal direction D1, and each of the insulation patterns 42 may be located between the second stacked structures BL adjacent to each other. In some embodiments, one of the second stacked structures BL may be disposed adjacent to the peripheral structure AR straddled by the first stacked structure WL, and a width of this second stacked structure BL may be greater than a width of each of the other second stacked structures BL, but not limited thereto. Each of the second stacked structures BL may partially overlap the first stacked structures WL in the vertical direction D3, and each of the second stacked structures BL may include an electrically conductive layer 34, an electrically conductive layer 36, and a capping layer 38 stacked in the vertical direction D3. In some embodiments, the electrically conductive layer 34 may include a nonmetallic electrically conductive material (such as doped polycrystalline silicon or other suitable nonmetallic electrically conductive materials), the electrically conductive layer 36 may include a metallic electrically conductive material (such as tungsten, titanium, or other suitable metallic electrically conductive materials), and the capping layer 38 may include a nitride insulation material, an oxynitride insulation material, or other suitable insulation materials. In addition, the insulation pattern 42 may include a nitride insulation material or other suitable insulation materials. In some embodiments, the first stacked structure WL may be a word line structure (such as a buried word line structure), the second stacked structure BL may be a bit line structure, and the semiconductor device 101 may be a memory device, but not limited thereto. In addition, a distance DS2 may be defined as a distance between the contact structure CT1 and the second stacked structure BL disposed adjacent to the peripheral structure AR straddled by the first stacked structure WL in the horizontal direction D1. In some embodiments, the edge 26E of the capping layer 26 and the sidewall SW of the second portion 24B of the electrically conductive layer 24 may be disposed above the peripheral structure AR in the vertical direction D3, and the distance DS1 defined above may be less than the distance DS2 accordingly, but not limited thereto.

In some embodiments, the semiconductor device 101 may further include a mask layer 32. The mask layer 32 is disposed on the first stacked structure WL, a part of each of the second stacked structures BL may be disposed on the mask layer 32, and the mask layer 32 may include silicon nitride, silicon oxide, silicon oxynitride, a combination of the materials described above, or other suitable mask materials. In addition, the semiconductor device 101 may further include a plurality of sidewall structures SP disposed on sidewalls of corresponding second stacked structures BL, respectively, and each of the sidewall structures SP may include a multi-layer structure made of different insulation materials, but not limited thereto. For example, the sidewall structure SP may include a sidewall spacer S1, a sidewall spacer S2, and a sidewall spacer S3 sequentially stacked from the sidewall of the second stacked structure BL outwards in the horizontal direction D1, and the sidewall spacer S1, the sidewall spacer S2, and the sidewall spacer S3 may be a nitride insulation material, an oxide insulation material, and a nitride insulation material, respectively, or other combinations of the materials described above, but not limited thereto. In some embodiments, the semiconductor device 101 may further include a dielectric layer 44, a dielectric layer 46, and contact structures CT2. The dielectric layer 44 may cover the first stacked structure WL, and the dielectric layer 46 may be disposed on the dielectric layer 44, the second stacked structures BL, and the insulation patterns 42. In some embodiments, the contact structure CT1 may penetrate through the dielectric layer 46, the dielectric layer 44, and the dielectric capping layer 28 located above the second portion 24B of the electrically conductive layer 24 in the vertical direction D3 for contacting and being electrically connected with the second portion 24B of the electrically conductive layer 24 in the first stacked structure WL, the contact structure CT2 may be disposed on the peripheral region, and the contact structure CT2 may penetrate through the dielectric layer 46 and the capping layer 38 in the vertical direction D3 for contacting and being electrically connected with electrically conductive layer 36 in the corresponding second stacked structure BL. In addition, the contact structure CT1 and the contact structure CT2 may include the same material composition, such as including a barrier layer 52 and an electrically conductive layer 54 disposed on the barrier layer 52, but not limited thereto. The barrier layer 52 may include titanium nitride, tantalum nitride, or other suitable electrically conductive barrier materials, and the electrically conductive layer 54 may include copper, aluminum, tungsten, molybdenum, an alloy of the materials described above, a composite layer structure of the materials described above, or other suitable electrically conductive materials. In some embodiments, the contact structure CT1 and other contact structures (such as the contact structure CT2 described above, but not limited thereto) may be formed concurrently by the same manufacturing process. By the thickness distribution design of the electrically conductive layer 24 in the first stacked structure WL in this embodiment, the etching amount required for forming the opening OP1 corresponding to the contact structure CT1 (such as an over etching amount) may be reduced. For example, in the condition that the contact structure CT1 contacts the second portion 24B of the electrically conductive layer 24 with the higher top surface and the second portion 24B is not covered by the capping layer 26, the thickness of the dielectric capping layer 26 required to be etched in the step of forming the opening OP1 may be reduced, and there is not any capping layer 26 required to be etched in the step of forming the opening OP1. Therefore, the time and/or the strength of the etching process may be reduced, and the negative influence generated by serious over etching in the step of forming openings corresponding to other contact structures concurrently (such as over etching damage to components locate corresponding to other contact structures) may be avoided accordingly. The first portion 24A of the electrically conductive layer 24, which occupies a larger portion of the electrically conductive layer 24 and is relatively thin, may still be covered by the capping layer 26 for providing the protection effect, and the manufacturing yield of the semiconductor device may be enhanced accordingly.

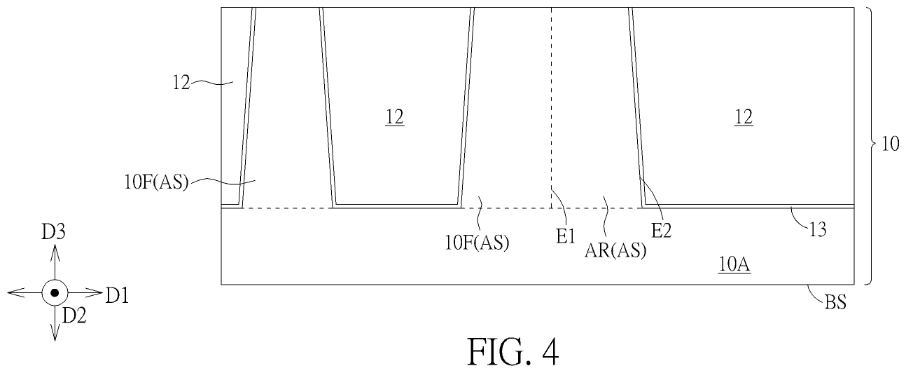

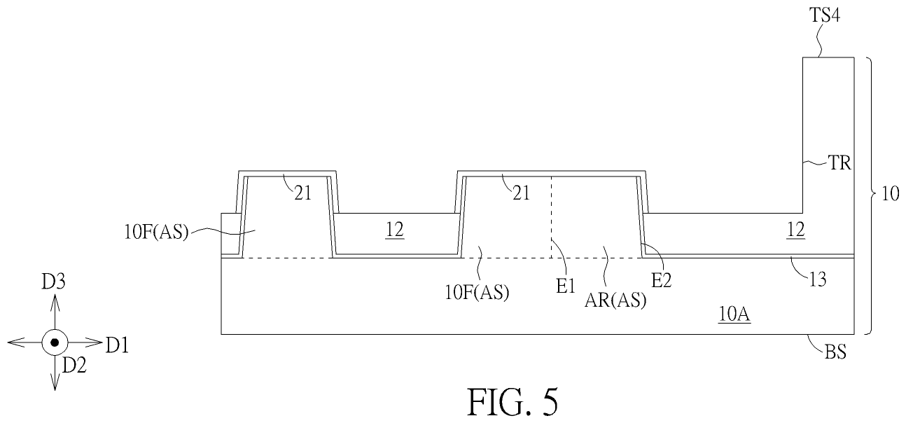

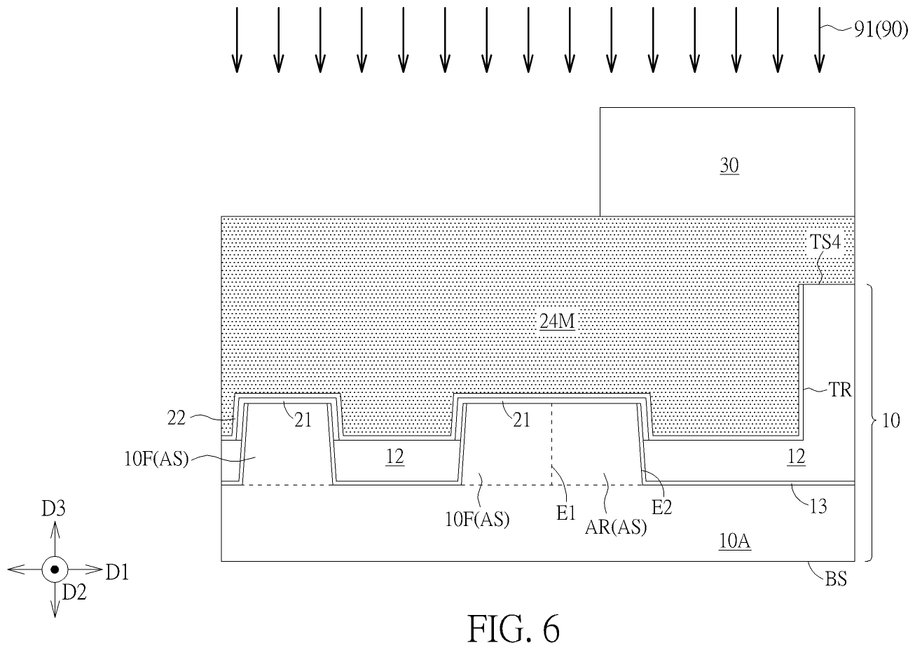

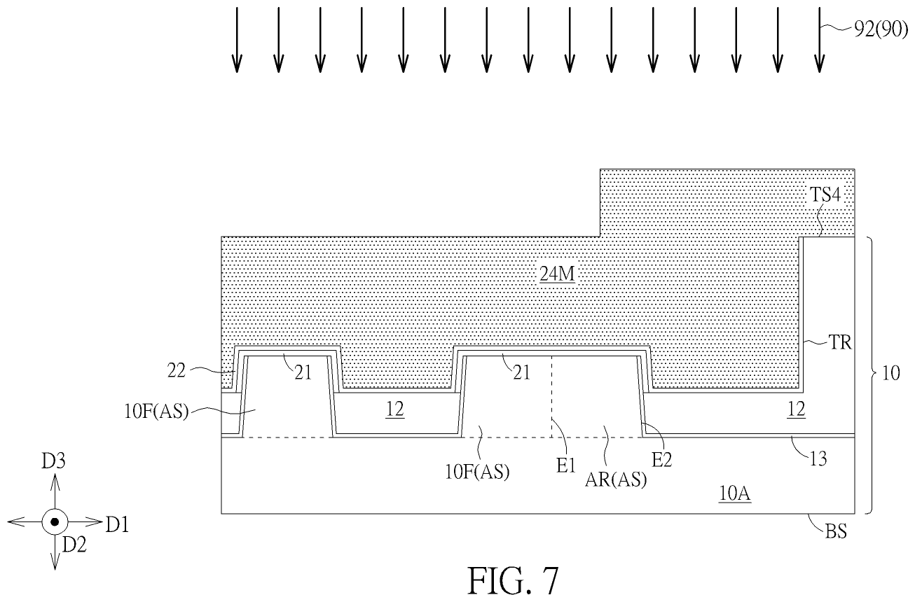

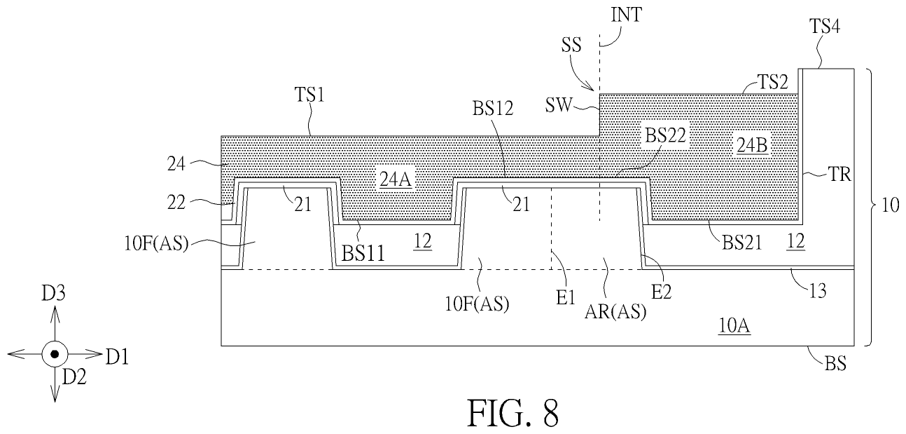

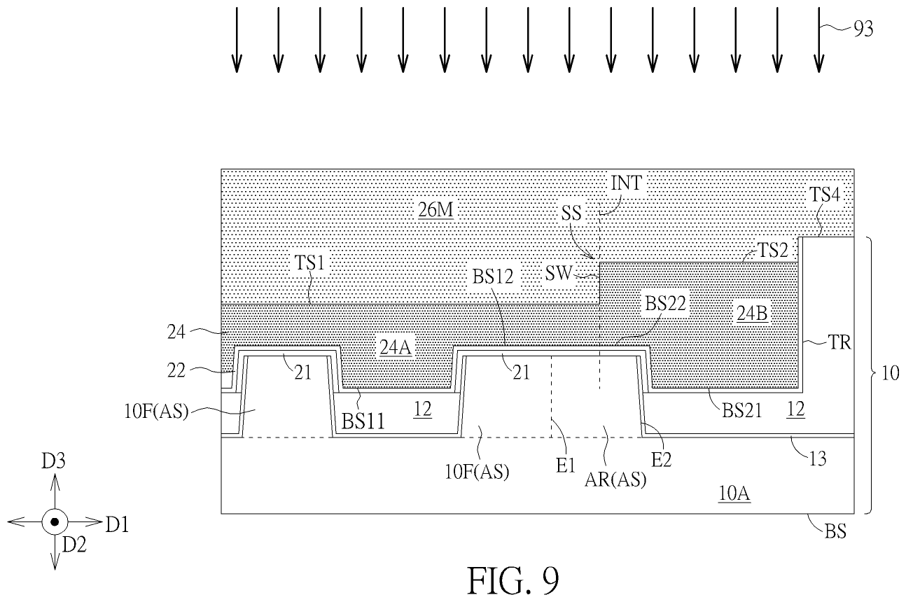

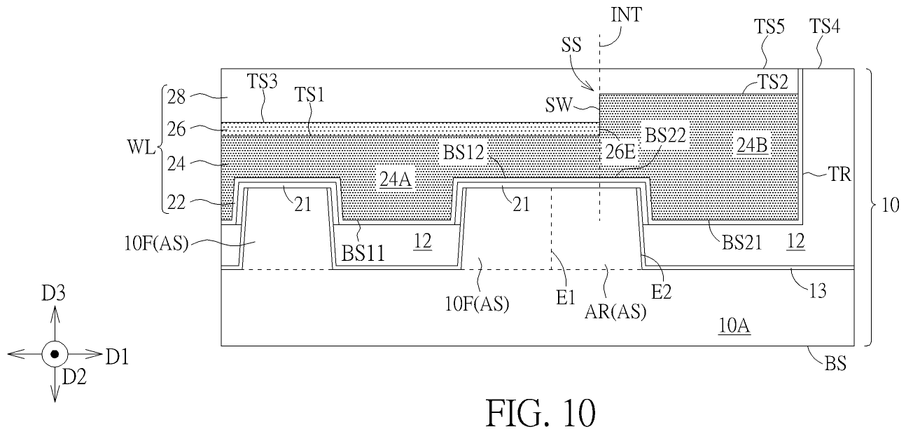

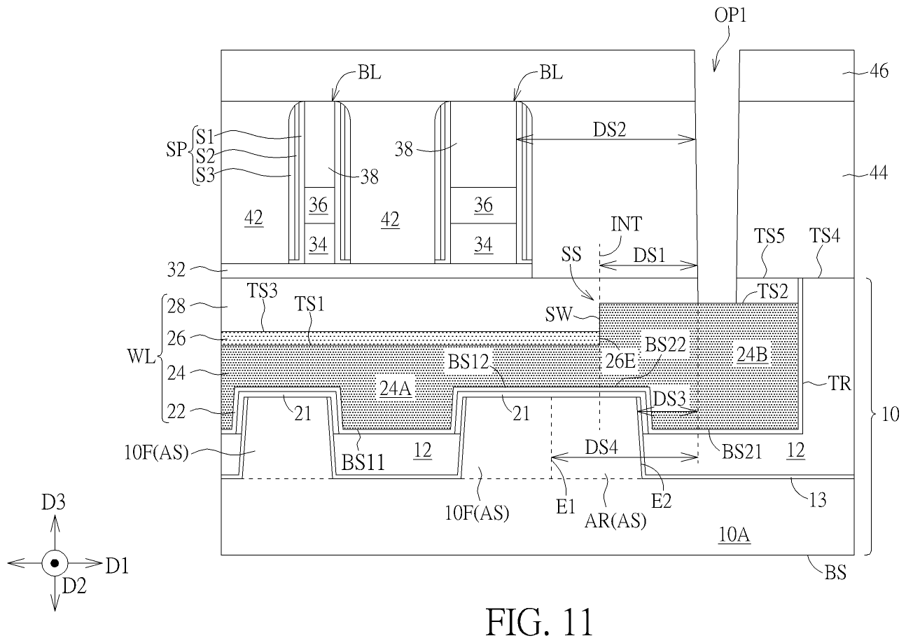

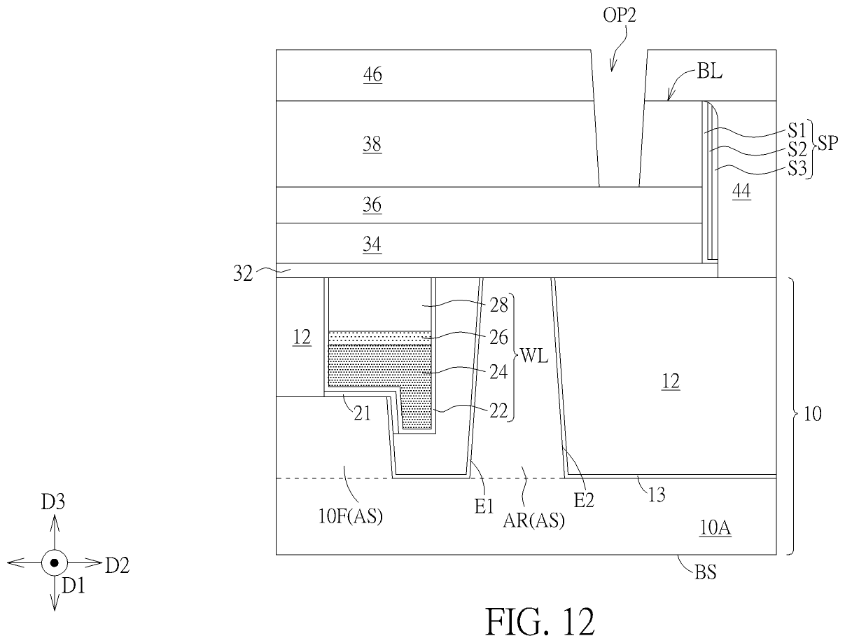

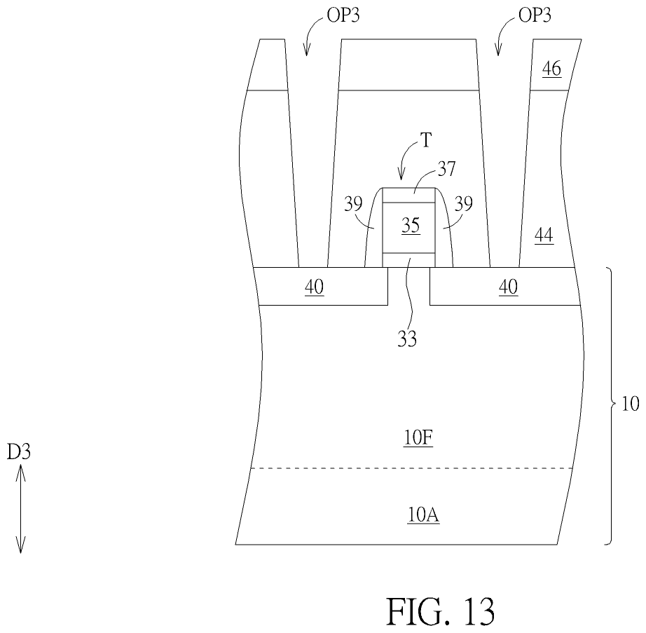

Please refer to FIGS. 1-13. FIGS. 4-13 are schematic drawings illustrating a manufacturing method of a semiconductor device according to an embodiment of the present invention, wherein FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, FIG. 12 is another cross-sectional schematic drawing illustrating the condition of FIG. 11, and FIG. 13 is a cross-sectional schematic drawing illustrating another region under the condition of FIG. 11. In some embodiments, FIG. 2 may be regarded as a schematic drawing in a step subsequent to FIG. 11, and FIG. 3 may be regarded as a schematic drawing in a step subsequent to FIG. 12, but not limited thereto. As shown in FIG. 1, FIG. 2, and FIG. 3, a manufacturing method of a semiconductor device is provided in an embodiment of the present invention and includes the following steps. The semiconductor substrate 10 is provided. The semiconductor substrate 10 includes the isolation structure 12 and the active structure AS defined by the isolation structure 12. The active structure AS includes at least one fin-shaped structure 10F. The first stacked structure WL is formed in the semiconductor substrate 10. The first stacked structure WL extends in the horizontal direction D1 and is disposed straddling the fin-shaped structure 10F, and the first stacked structure WL includes the electrically conductive layer 24, the capping layer 26, and the dielectric capping layer 28. The electrically conductive layer 24 includes the first portion 24A and the second portion 24B. The top surface TS2 of the second portion 24B is higher than the top surface TS1 of the first portion 24A in the vertical direction D3, and the distance DS6 between the top surface TS2 of the second portion 24B and the isolation structure 12 in the vertical direction D3 is greater than the distance DS5 between the top surface TS1 of the first portion 24A and the isolation structure 12 in the vertical direction D3. The capping layer 26 is disposed on the electrically conductive layer 24. The dielectric capping layer 28 is disposed on the capping layer 26 and the electrically conductive layer 24. Subsequently, the contact structure CT1 is formed. The contact structure CT1 directly contacts the second portion 24B of the electrically conductive layer 24 and is electrically connected with the first stacked structure WL.

Specifically, the manufacturing method of the semiconductor device in this embodiment may include but is not limited to the following steps. As shown in FIG. 4, the fin-shaped structures 10F and the peripheral structure AR described above may be formed by performing a patterning process to the semiconductor substrate 10, and the stress material layer 13 and the isolation structure 12 may be formed after the step of forming the fin-shaped structures 10F and the peripheral structure AR. Subsequently, as shown in FIG. 4 and FIG. 5, the trench TR may be formed in the semiconductor substrate 10 by removing a part of the fin-shaped structure 10F, a part of the peripheral structure AR, a part of the stress material layer 13, and a part of the isolation structure 12. The trench may extend in the horizontal direction D1 and be disposed straddling the fin-shaped structures 10F and the peripheral structure AR, and the trench TR may be partly located in the cell region and partly located in the peripheral region accordingly. In some embodiments, for forming the first stacked structure straddling the fin-shaped structures 10F and increasing the surface area of the fin-shaped structures 10F covered by the first stacked structure in the subsequent process, a portion of the fin-shaped structure 10F and a portion of the peripheral structure AR may protrude upwards from the bottom of the trench TR by adjusting an etching process used to form the trench TR. After the step of forming the trench TR, the exposed stress material layer 13 and the exposed fin-shaped structure 10F may be oxidized for forming the oxide layer 21. Subsequently, as shown in FIGS. 6-8, the dielectric layer 22 and the electrically conductive layer 24 may be formed in the trench TR. The dielectric layer 22 may be conformally formed in the trench TR and conformally formed on the surface of the isolation structure 12 and the surface of the oxide layer 21, and the electrically conductive layer 24 is formed on the dielectric layer 22.

The method of forming the electrically conductive layer 24 in this embodiment may include but is not limited to the following steps. As shown in FIG. 6, an electrically conductive material 24M may be formed, the electrically conductive material 24M may be partly formed in the trench TR, the trench TR may be filled with the electrically conductive material 24M, and the electrically conductive material 24M may be partly formed outside the trench TR. Subsequently, as shown in FIGS. 6-8, a removing process 90 may be performed to the electrically conductive material 24M for removing a part of the electrically conductive material 24M and forming the electrically conductive layer 24. In some embodiments, the removing process 90 may include but is not limited to the following steps. Firstly, a patterned mask layer 30 may be formed on the electrically conductive material 24M, and a first removing step 91 may be performed to the electrically conductive material 24M by using the patterned mask layer 30 as a mask. The patterned mask layer 30 may cover a portion of the electrically conductive material 24M located in the trench TR in the vertical direction D3, and a portion of the electrically conductive material 24M without being covered by the patterned mask layer 30 may be removed by the first removing step 91. After the first removing step 91, a second removing step 92 may be performed to the electrically conductive material 24M. The electrically conductive material 24M located in the trench TR may be partially removed by the second removing step 92 to become the electrically conductive layer 24, and the patterned mask layer 30 may be removed after the first removing step 91 and before the second removing step 92. In some embodiments, the first removing step 91 and the second removing step 92 may be etching steps (such as anisotropic dry etching steps, but not limited thereto) or other suitable removing approaches. The patterned mask layer 30 may be the etching mask in the first removing step 91, and there may be not any etching mask in the second removing step 92. Therefore, the second removing step 92 may be regarded as an etching back process, but not limited thereto.

In addition, after the first removing step 91 and before the second removing step 92, the electrically conductive material 24M may include portions with different heights, and a part of the electrically conductive material 24M may be located outside the trench TR still. After the second removing step 92, the electrically conductive material 24M located outside the trench TR may be completely removed, and the top surface TS2 of the second portion 24B of the electrically conductive layer 24 is lower than a top surface TS4 of the isolation structure 12 in the vertical direction D3 so as to save the space in the trench TR for the capping layer and the dielectric capping layer subsequently formed. Subsequently, as shown in FIG. 9, a capping layer material 26M may be formed. The capping layer material 26M may cover the electrically conductive layer 24, the trench TR may be filled with the capping layer material 26M, and the capping layer material 26M may be partly formed outside the trench TR. Subsequently, a removing process 93 may be performed to the capping layer material 26M for completely remove the capping layer material 26M located outside the trench TR and the capping layer material 26M located above the second portion 24B of the electrically conductive layer 24 and thinning the capping layer material 26M located above the first portion 24A of the electrically conductive layer 24, so as to form the capping layer 26 illustrated in FIG. 10. In some embodiments, the removing process 93 may include an etching back process or other suitable removing approaches. It is worth noting that the method of forming the electrically conductive layer 24 and the capping layer 26 illustrated in FIG. 10 may include but is not limited to the manufacturing steps in FIGS. 6-9 described above. In some embodiments, the electrically conductive layer 24 including the first portion 24A and the second portion 24B with different surface heights and the capping layer 26 formed on the first portion 24A without being formed on the second portion 24B may be formed by other approaches according to some design considerations.

As shown in FIG. 11, after the step of forming the capping layer 26, the dielectric capping layer 28 may be formed in the trench TR for forming the first stacked structure WL. In other words, the capping layer 26 and the dielectric capping layer 28 may be formed in the trench TR after the removing process 90 illustrated in FIG. 6 and FIG. 7 described above. It is worth noting that, the method of forming the first stacked structure WL may include but is not limited to the manufacturing steps illustrated in FIGS. 5-10 described above. In some embodiments, the first stacked structure WL may be formed in the semiconductor substrate 10 by other approaches according to some design considerations.

As shown in FIG. 11 and FIG. 12, after the step of forming the first stacked structure WL, the mask layer 32, the second stacked structures BL, the sidewall structures SP, the insulation patterns 42, the dielectric layer 44, and the dielectric layer 46 described above may be formed. The opening OP1 penetrating through the dielectric layer 46, the dielectric layer 44, and the dielectric capping layer 28 and an opening OP2 penetrating through the dielectric layer 46 and the capping layer 38 may be formed subsequently. In the subsequent process, the contact structure located corresponding to the first stacked structure WL may be formed in the opening OP1, and the contact structure located corresponding to the second stacked structure BL may be formed in the opening OP2. In some embodiments, the opening OP1 and the opening OP2 may be formed concurrently by the same process, but not limited thereto. As shown in FIG. 11, FIG. 12, and FIG. 13, in some embodiments, a transistor structure T may be formed on the semiconductor substrate 10, and the transistor structure T may include a gate dielectric layer 33, a gate electrode 35, a gate capping layer 37, a sidewall structure 39, and source/drain regions 40. In some embodiments, the dielectric layer 44 may further cover the transistor structure T, an opening OP3 may penetrate through the dielectric layer 46 and the dielectric layer 44 in the vertical direction D3 and expose the source/drain region 40, and a contact structure located corresponding to the source/drain region 40 may be formed in the opening OP3 in the subsequent process.

In some embodiments, the opening OP1, the opening OP2, and the opening OP3 may be formed concurrently by the same process for manufacturing process simplification, but not limited thereto. In some embodiments, the gate electrode 35 of the transistor structure T may be formed on the fin-shaped structure 10F, and the fin-shaped structure 10F located corresponding to the transistor structure T and the above-mentioned fin-shaped structure 10F located corresponding to the first stacked structure WL may extend in the same direction or extend in different directions, respectively. As shown in FIG. 11, FIG. 12, FIG. 2, and FIG. 3, after the step of forming the opening OP1 and the opening OP2, the contact structure CT1 and the contact structure CT2 described above may be formed for forming the semiconductor device 101. It is worth noting that, by the thickness distribution design of the electrically conductive layer 24 in the first stacked structure WL in this embodiment, the etching amount required for forming the opening OP1 may be reduced, and the over etching amount for forming the opening OP2 and the opening OP3 may be reduced concurrently. The negative influence generated by compensating the over etching amount of the opening OP3 (such as the negative influence generated by increasing the depth of the source/drain region 40 on the operation performance of the transistor structure T, but not limited thereto) may be improved.

The following description will detail the different embodiments of the present invention. To simplify the description, the following description will detail the dissimilarities among different embodiments and the identical features will not be redundantly described. In addition, identical components in each of the following embodiments of the present invention are marked with identical symbols for making it easier for comparing the embodiments more conveniently.

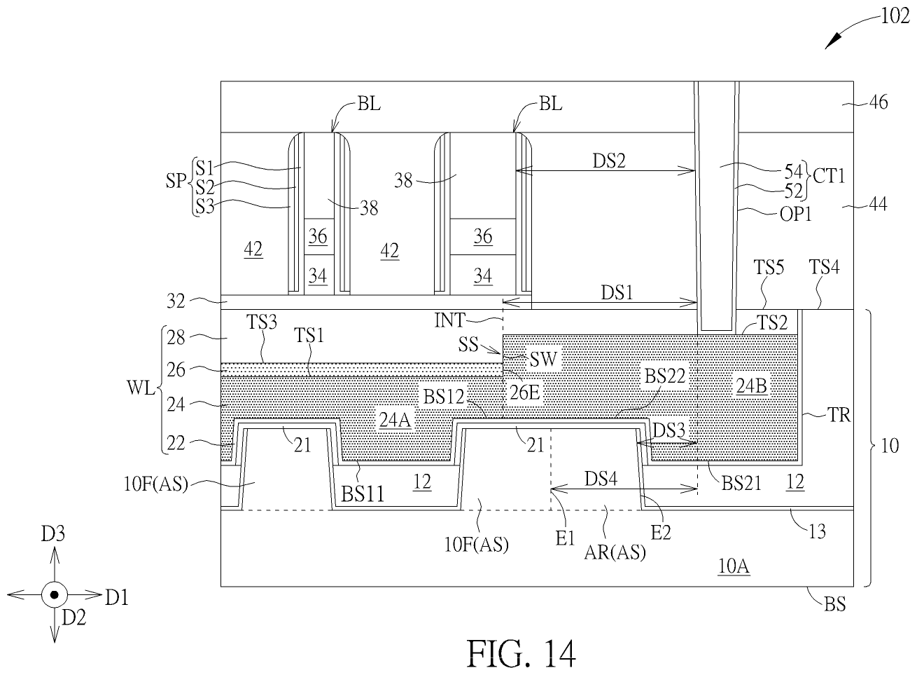

Please refer to FIG. 14. FIG. 14 is a cross-sectional schematic drawing illustrating a semiconductor device 102 according to a second embodiment of the present invention. In the semiconductor device 102, the edge 26E of the capping layer 26 and the sidewall SW of the second portion 24B of the electrically conductive layer 24 may be located above the fin-shaped structure 10F in the vertical direction D3 and located under the second stacked structure BL in the vertical direction D3. In this situation, the distance DS1 defined above may be greater than the distance DS2, the distance DS3, and the distance DS4 defined above, but not limited thereto.

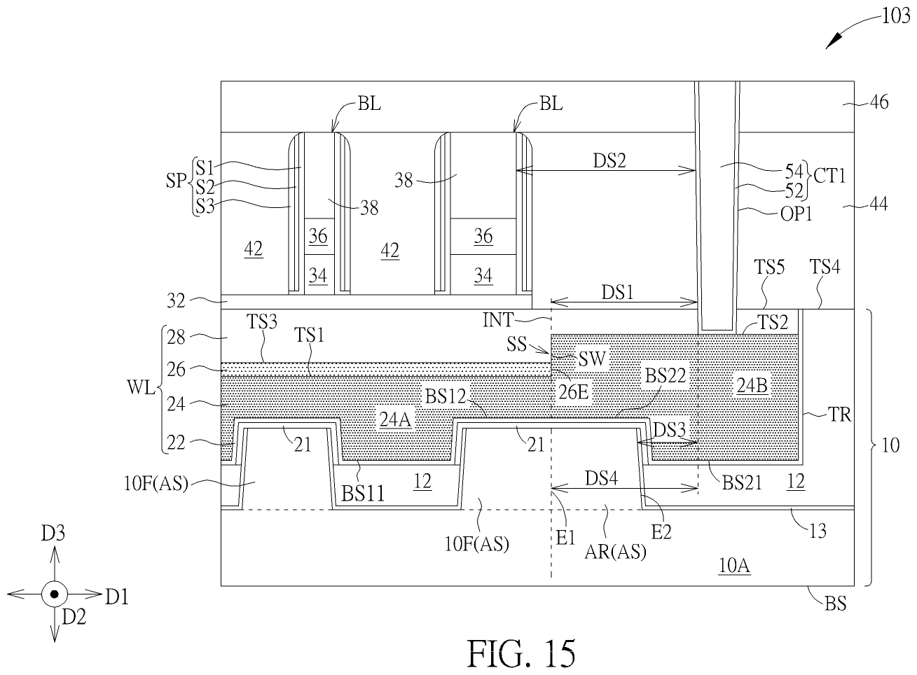

Please refer to FIG. 15. FIG. 15 is a cross-sectional schematic drawing illustrating a semiconductor device 103 according to a third embodiment of the present invention. In the semiconductor device 103, the edge 26E of the capping layer 26 and the sidewall SW of the second portion 24B of the electrically conductive layer 24 may be located above the interface between the fin-shaped structure 10F and the peripheral structure AR (such as above the edge E1) in the vertical direction D3. In this situation, the distance DS1 defined above may be less than the distance DS2 defined above and greater than the distance DS3 described above, but not limited thereto.

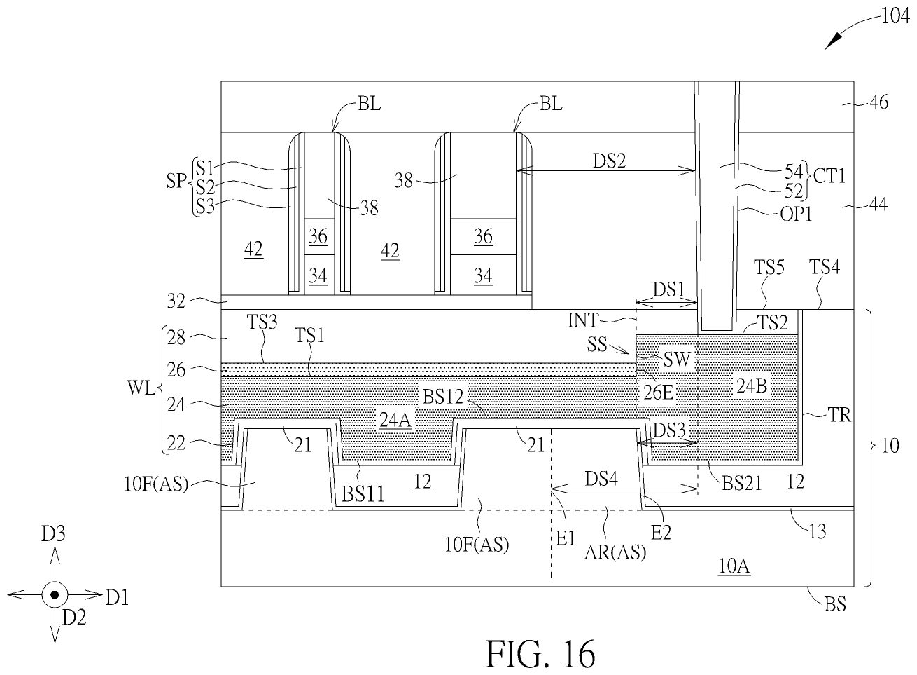

Please refer to FIG. 16. FIG. 16 is a cross-sectional schematic drawing illustrating a semiconductor device 104 according to a fourth embodiment of the present invention. In the semiconductor device 104, the edge 26E of the capping layer 26 and the sidewall SW of the second portion 24B of the electrically conductive layer 24 may be located above the edge E2 of the peripheral structure AR in the vertical direction D3. In this situation, the distance DS1 defined above may be less than the distance DS2 and the distance DS4 defined above and may be substantially equal to the distance DS3, but not limited thereto.

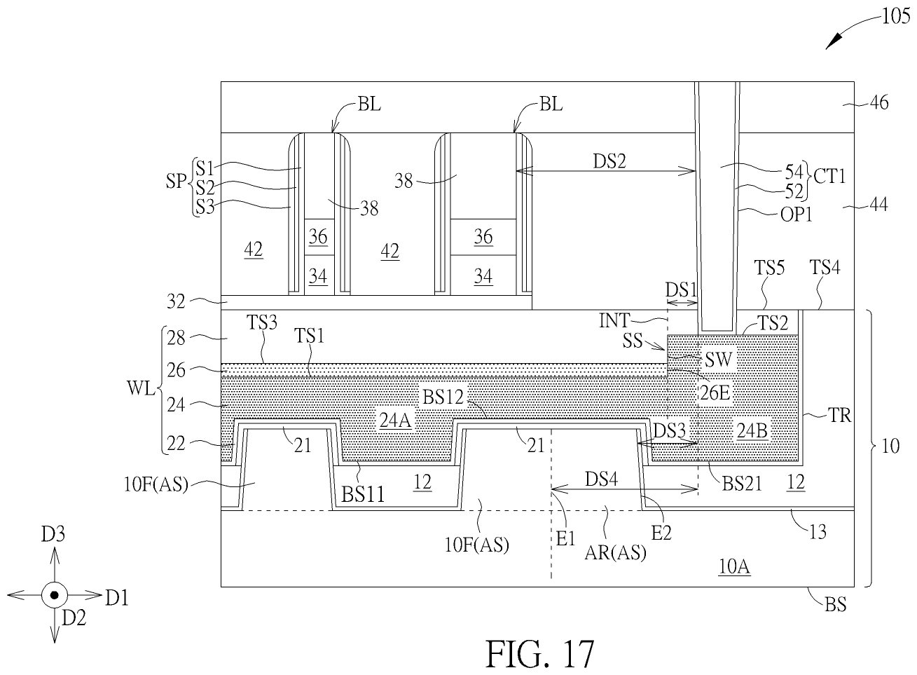

Please refer to FIG. 17. FIG. 17 is a cross-sectional schematic drawing illustrating a semiconductor device 105 according to a fifth embodiment of the present invention. In the semiconductor device 105, the edge 26E of the capping layer 26 and the sidewall SW of the second portion 24B of the electrically conductive layer 24 may be located above the peripheral region in the vertical direction D3. In this situation, the distance DS1 defined above may be less than the distance DS2, the distance DS3, and the distance DS4 defined above, but not limited thereto.

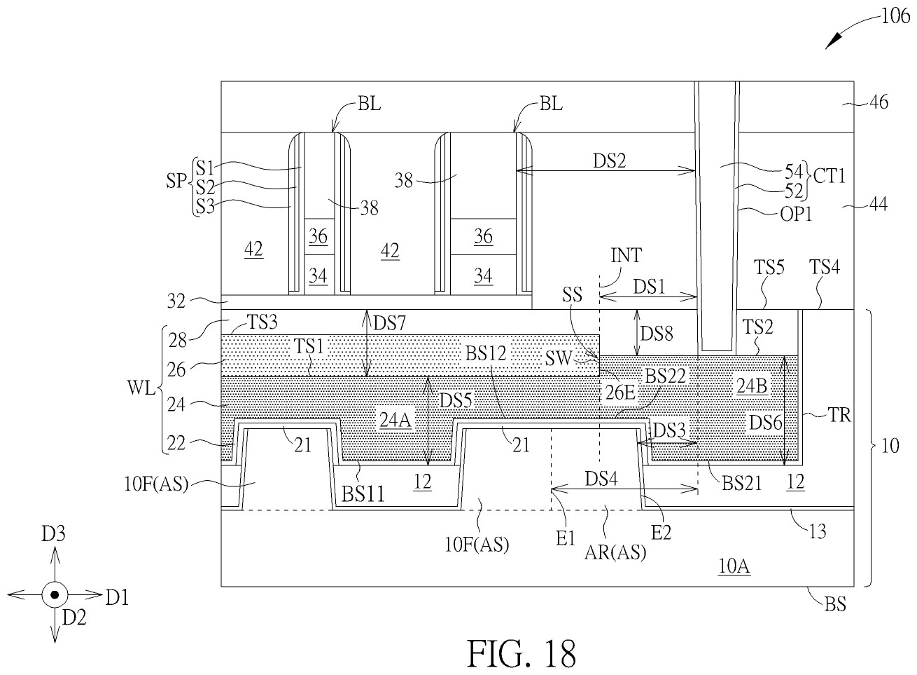

Please refer to FIG. 18. FIG. 18 is a cross-sectional schematic drawing illustrating a semiconductor device 106 according to a sixth embodiment of the present invention. In the semiconductor device 106, the top surface TS3 of the capping layer 26 may be higher than the top surface TS2 of the second portion 24B of the electrically conductive layer 24 in the vertical direction D3.

To summarize the above descriptions, in the semiconductor device and the manufacturing method thereof according to the present invention, the thickness distribution design of the electrically conductive layer in the first stacked structure may be used to reduce the etching amount required for forming the opening corresponding to the contact structure, and it is beneficial for integrating the manufacturing process of the contact structure and the manufacturing processes of other contact structures. The purposes of simplifying the overall manufacturing process and improving the manufacturing yield of the semiconductor device may be achieved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a semiconductor substrate comprising an isolation structure and an active structure defined by the isolation structure, wherein the active structure comprises at least one fin-shaped structure;
a first stacked structure disposed in the semiconductor substrate, wherein the first stacked structure extends in a horizontal direction and is disposed straddling the fin-shaped structure, and the first stacked structure comprises:
an electrically conductive layer comprising:
a first portion; and
a second portion, wherein a top surface of the second portion is higher than a top surface of the first portion in a vertical direction, and a distance between the top surface of the second portion and the isolation structure in the vertical direction is greater than a distance between the top surface of the first portion and the isolation structure in the vertical direction;
a capping layer disposed on the electrically conductive layer; and
a dielectric capping layer disposed on the capping layer and the electrically conductive layer; and
a contact structure directly contacting the second portion of the electrically conductive layer and electrically connected with the first stacked structure.

2. The semiconductor device according to claim 1, wherein the top surface of the second portion is higher than a top surface of the capping layer in the vertical direction.

3. The semiconductor device according to claim 1, wherein a surface of the electrically conductive layer comprises a ladder-shaped structure, and the top surface of the first portion and the top surface of the second portion are located at two opposite sides of the ladder-shaped structure in the horizontal direction, respectively.

4. The semiconductor device according to claim 1, wherein the contact structure directly contacts the top surface of the second portion.

5. The semiconductor device according to claim 1, wherein a distance between a top surface of the dielectric capping layer and the top surface of the second portion of the electrically conductive layer in the vertical direction is less than a distance between the top surface of the dielectric capping layer and the top surface of the first portion of the electrically conductive layer in the vertical direction.

6. The semiconductor device according to claim 1, wherein the top surface of the second portion of the electrically conductive layer directly contacts the dielectric capping layer.

7. The semiconductor device according to claim 1, wherein a sidewall of the second portion of the electrically conductive layer faces the capping layer in the horizontal direction, and the capping layer directly contacts the sidewall of the second portion.

8. The semiconductor device according to claim 7, wherein the dielectric capping layer directly contacts the sidewall of the second portion of the electrically conductive layer.

9. The semiconductor device according to claim 7, wherein the sidewall of the second portion of the electrically conductive layer is connected with the top surface of the first portion and the top surface of the second portion to form a ladder-shaped structure.

10. The semiconductor device according to claim 7, further comprising:
a second stacked structure disposed above the semiconductor substrate, wherein a distance between the sidewall of the second portion of the electrically conductive layer and the contact structure in the horizontal direction is less than a distance between the second stacked structure and the contact structure in the horizontal direction.

11. The semiconductor device according to claim 1, wherein an edge of the capping layer in the horizontal direction faces the contact structure and is located above the fin-shaped structure in the vertical direction.

12. The semiconductor device according to claim 1, wherein the active structure further includes a peripheral structure surrounding the fin-shaped structure, and the first stacked structure extends in the horizontal direction and is disposed straddling the peripheral structure.

13. The semiconductor device according to claim 12, wherein an edge of the capping layer in the horizontal direction faces the contact structure and is located above the peripheral structure in the vertical direction.

14. The semiconductor device according to claim 12, wherein a distance between an edge of the capping layer in the horizontal direction and the contact structure is less than a distance between the peripheral structure and the contact structure in the horizontal direction.

15. A manufacturing method of a semiconductor device, comprising:
providing a semiconductor substrate comprising an isolation structure and an active structure defined by the isolation structure, wherein the active structure comprises at least one fin-shaped structure;
forming a stacked structure in the semiconductor substrate, wherein the stacked structure extends in a horizontal direction and is disposed straddling the fin-shaped structure, and the stacked structure comprises:
an electrically conductive layer comprising:
a first portion; and
a second portion, wherein a top surface of the second portion is higher than a top surface of the first portion in a vertical direction, and a distance between the top surface of the second portion and the isolation structure in the vertical direction is greater than a distance between the top surface of the first portion and the isolation structure in the vertical direction;
a capping layer disposed on the electrically conductive layer; and
a dielectric capping layer disposed on the capping layer and the electrically conductive layer; and
forming a contact structure, wherein the contact structure directly contacts the second portion of the electrically conductive layer and is electrically connected with the stacked structure.

16. The manufacturing method of the semiconductor device according to claim 15, wherein a method of forming the stacked structure comprises:
forming a trench in the semiconductor substrate, wherein the trench extends in the horizontal direction and is disposed straddling the fin-shaped structure;
forming an electrically conductive material in the trench; and
performing a removing process to the electrically conductive material for removing a part of the electrically conductive material and forming the electrically conductive layer.

17. The manufacturing method of the semiconductor device according to claim 16, wherein the removing process comprises:
forming a patterned mask layer on the electrically conductive material and performing a first removing step to the electrically conductive material by using the patterned mask layer as a mask, wherein the patterned mask layer covers a portion of the electrically conductive material located in the trench in the vertical direction, and a portion of the electrically conductive material without being covered by the patterned mask layer is removed by the first removing step; and
performing a second removing step to the electrically conductive material after the first removing step, wherein the electrically conductive material located in the trench is partially removed by the second removing step to become the electrically conductive layer, and the patterned mask layer is removed after the first removing step and before the second removing step.

18. The manufacturing method of the semiconductor device according to claim 16, wherein the method of forming the stacked structure further comprises:
forming the capping layer and the dielectric capping layer in the trench after the removing process.

19. The manufacturing method of the semiconductor device according to claim 15, wherein the contact structure directly contacts the top surface of the second portion.

20. The manufacturing method of the semiconductor device according to claim 15, wherein the capping layer directly contacts the top surface of the first portion of the electrically conductive layer, and the dielectric capping layer directly contacts the top surface of the second portion of the electrically conductive layer.
